(19) United States
(12) Patent Application Publication
(10) Pub. No.: US 2026/0216843 A1
(43) Pub. Date: Jul. 30, 2026

(54) CHEMICAL MECHANICAL POLISHING APPARATUS

(71) Applicant: Samsung Electronics Co., Ltd., Suwon-si (KR)

(72) Inventors: Dong Hoon KWON, Suwon-si (KR); Seung Yong YU, Suwon-si (KR); Jin-Woo BAE, Suwon-si (KR); Young In KIM, Suwon-si (KR); So Hyeon PARK, Suwon-si (KR); Ji Hoon PARK, Suwon-si (KR); Hyo Jin PARK, Suwon-si (KR); In Hak JEON, Suwon-si (KR); Byung Soo JOO, Suwon-si (KR)

(21) Appl. No.: 19/439,137

(22) Filed: Jan. 2, 2026

(30) Foreign Application Priority Data
Jan. 10, 2025 (KR) 10-2025-0003979

(51) Int. Cl. B24B 47/10; B24B 37/005; B24B 37/10

(52) U.S. Cl. CPC B24B 47/10; B24B 37/005; B24B 37/107

(57) ABSTRACT

A chemical mechanical polishing apparatus includes a head configured to mount a wafer thereon, a spindle connected to the head; a support horizontally extending from the spindle, and a shock wave module disposed on a lower surface of the support, configured to generate a shock wave that is applied to the head.

### CROSS-REFERENCE TO RELATED APPLICATION

This application claims priority under 35 U.S.C. 119 to Korean Patent Application No. 10-2025-0003979 filed on January 10, 2025 in the Korean Intellectual Property Office, the content of which is herein incorporated by reference in its entirety.

### BACKGROUND

### Technical Field

The present disclosure relates to a chemical mechanical polishing apparatus.

### Description of Related Art

A chemical mechanical polishing (CMP) process may be used to planarize a wafer in manufacturing a semiconductor device. In the chemical mechanical polishing process, for a uniform profile of the wafer, a technique of tilting a head on which the wafer is mounted may be used.

### SUMMARY

According to some embodiments, a chemical mechanical polishing apparatus is capable of controlling tilting of a head without contacting the head.

According to an aspect of the disclosure, there is provided a chemical mechanical polishing apparatus including a head configured to mount a wafer thereon, a spindle vertically extending from the head, a support horizontally extending from the spindle, and a shock wave module disposed on a lower surface of the support, and configured to generate a shock wave that is applied to the head.

According to an aspect of the disclosure, there is provided a chemical mechanical polishing apparatus including a head configured to mount a wafer thereon, a spindle connected to the head, a support connected to the spindle, a head pad disposed on an upper surface of the head; a coupler disposed between the head and the head pad; and a shock wave module connected to a lower surface of the support, and configured to generate a shock wave and apply the shock wave to the head pad. The shock wave module may be spaced apart from the head pad.

According to an aspect of the disclosure, there is provided a chemical mechanical polishing apparatus including a head configured to mount a wafer thereon, a spindle vertically extending from the head, a plurality of supports each extending from the spindle horizontally, a plurality of head pads disposed on the head, and a plurality of shock wave modules, each connected to a lower surface of a corresponding support and positioned vertically above a corresponding head pad to generate and apply a shock wave to the corresponding head pad.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a plan view of a chemical mechanical polishing apparatus according to some embodiments;

FIG. 2 is a cross-sectional view of the chemical mechanical polishing apparatus of FIG. 1;

FIGS. 3 to 5 are plan views illustrating a coupler of FIG. 2;

FIGS. 6 and 7 are plan views of a chemical mechanical polishing apparatus according to some embodiments;

FIG. 8 is a cross-sectional view of the chemical mechanical polishing apparatus of FIG. 7;

FIG. 9 is a cross-sectional view illustrating an operation of the chemical mechanical polishing apparatus of FIG. 2;

FIG. 10 is a cross-sectional view for illustrating a shock wave module of FIG. 2;

FIG. 11 is a plan view for illustrating a conductive support and a plurality of piezoelectric elements of FIG. 10;

FIGS. 12 and 13 are diagrams for illustrating an operation of the shock wave module of FIGS. 10 and 11;

FIG. 14 is a cross-sectional view of the chemical mechanical polishing apparatus of FIG. 1;

FIG. 15 is a cross-sectional view for illustrating the shock wave module of FIG. 14;

FIG. 16 is a plan view for illustrating the shock wave module of FIG. 15;

FIGS. 17 and 18 are diagrams for illustrating an operation of the shock wave module of FIGS. 15 and 16;

FIG. 19 is a cross-sectional view illustrating an operation of the chemical mechanical polishing apparatus of FIG. 14;

FIGS. 20 to 22 are cross-sectional views of the chemical mechanical polishing apparatus of FIG. 1;

FIG. 23 is a plan view of a chemical mechanical polishing apparatus according to some embodiments;

FIG. 24 is a cross-sectional view of the chemical mechanical polishing apparatus of FIG. 23;

FIG. 25 is a plan view for illustrating an auxiliary support of the chemical mechanical polishing apparatus according to some embodiments; and

FIG. 26 is a cross-sectional view of the chemical mechanical polishing apparatus of FIG. 25.

### DETAILED DESCRIPTIONS

Although the first, second, and the like are used herein to describe various elements or components, it will be appreciated that these elements or components are not limited by these terms. These terms are merely used to distinguish one element or component from another element or component. Accordingly, a first element or component described herein may be referenced elsewhere (e.g., in a claim) as a second element or component.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact. As the state of contact is binary (either in contact or not in contact), it will be appreciated that “contact” has the same scope as any use of “direct contact.”

Items described in the singular herein may be provided in plural, as can be seen, for example, in the drawings. Thus, the description of a single item that is provided in plural should be understood to be applicable to the remaining plurality of items unless context indicates otherwise.

Spatially relative terms, such as “lower,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. The device may be otherwise oriented (rotated 90 degrees or at other orientations) and the spatially relative descriptors used herein interpreted accordingly.

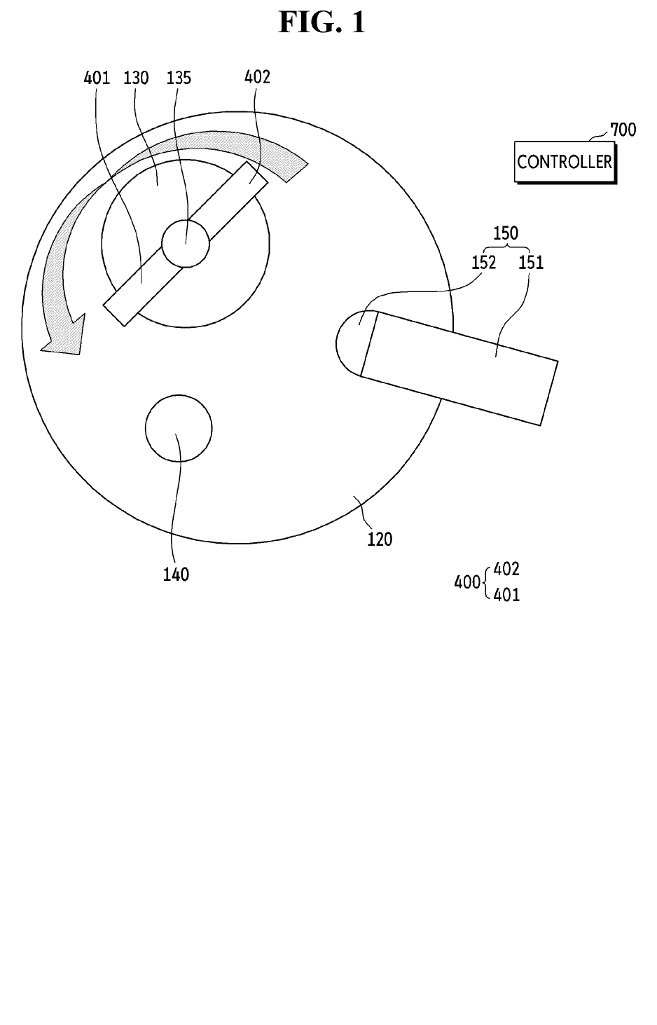

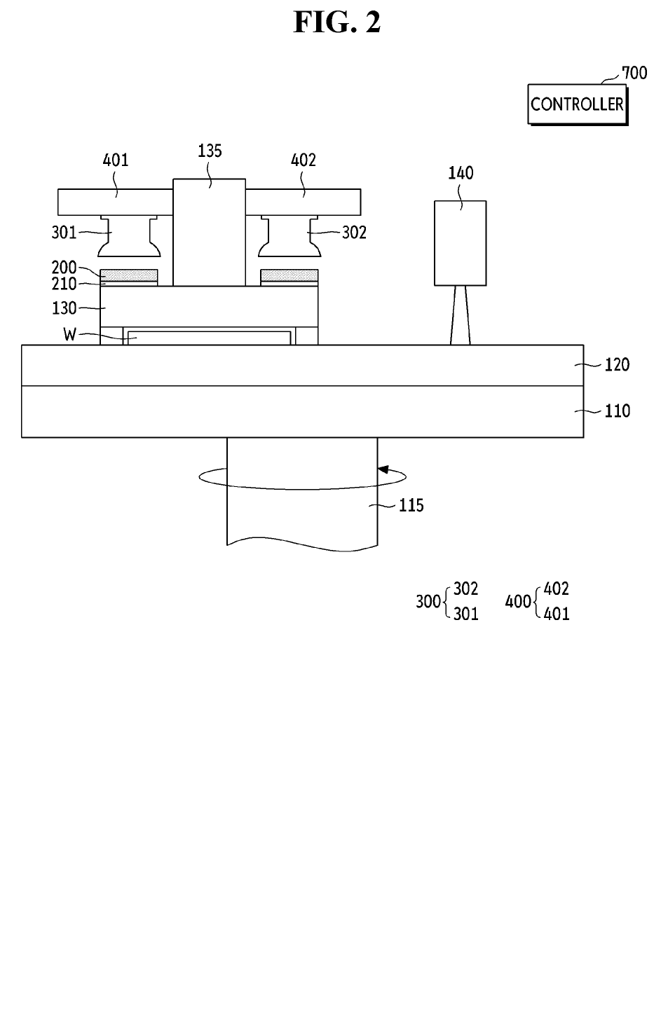

FIG. 1 is a plan view of a chemical mechanical polishing apparatus according to some embodiments. FIG. 2 is a cross-sectional view of the chemical mechanical polishing apparatus of FIG. 1. In FIG. 2, the conditioner 150 of FIG. 1 is not shown.

Referring to FIGS. 1 and 2, the chemical mechanical polishing apparatus according to some embodiments may include a platen 110, a drive shaft 115, a polishing pad 120, a head 130, a spindle 135, a slurry supply 140, a conditioner 150, a head pad 200, a coupler 210, a shock wave module 300, a support 400, and a controller 700.

The platen 110 may be coupled to the drive shaft 115. The drive shaft 115 may extend in a vertical direction. The platen 110 may rotate about the drive shaft 115 in a predetermined direction, for example, in a counterclockwise direction. For example, a motor for rotating the platen 110 may be connected to the drive shaft 115. The platen 110 may have a disk shape.

The polishing pad 120 may be disposed on an upper surface of the platen 110. The polishing pad 120 may also rotate about the drive shaft 115 as the platen 110 rotates.

The head 130 may be positioned on the polishing pad 120. The head 130 may be coupled to the spindle 135. The spindle 135 may extend in a vertical direction. The head 130 may rotate about the spindle 135 in a predetermined direction, for example, counterclockwise. For example, a motor for rotating the head 130 may be connected to the spindle 135. The head 130 may have a disk shape.

The head 130 may mount a wafer W thereon. The head 130 may bring the wafer W into contact with the polishing pad 120. The head 130 may be pressed toward the polishing pad 120 so that the wafer W is polished.

The slurry supply 140 may be disposed on the polishing pad 120. The slurry supply 140 may supply slurry to the polishing pad 120. For example, the slurry supply 140 may be positioned between the head 130 and the conditioner 150 along the rotation path of the platen 110. For example, the head 130, the slurry supply 140, and the conditioner 150 may be sequentially arranged along the rotation path of the platen 110. The conditioner 150 may serve to regenerate the surface of the polishing pad 120 by removing glazing and restoring its texture, thereby ensuring stable material removal rates and uniform polishing performance. Accordingly, the slurry supplied from the slurry supply 140 may be more smoothly provided to the polishing pad 120.

Chemical mechanical polishing of the wafer W may be performed using the slurry supplied from the slurry supply 140. The polishing pad 120 may chemically and mechanically polish a film formed on the wafer W, for example, a metal film, an insulating film and/or a semiconductor film, using the slurry provided from the slurry supply 140. The slurry may include an oxidizing agent.

The conditioner 150 may be positioned on the polishing pad 120. The conditioner 150 may include an arm 151 configured to perform a sweeping motion, and a disk 152 connected to the arm 151 to perform a sweeping motion and to polish a surface of the polishing pad 120 to adjust surface conditioning of the polishing pad 120.

One or more head pads 200 may be disposed on the head 130. Each head pad 200 may be spaced apart from the spindle 135. A coupler 210 may be interposed between each head pad 200 and the head 130 and adhere the head pad 200 to an upper surface of the head 130. The head pad 200 may serve to protect the head from external contact or mechanical impact.

For example, the head pad 200 may include a metal and the coupler 210 may include a magnetic material (forming a magnet) such that the head pad 200 may be magnetically attached to the head 130. In another example, the coupler 210 may be formed of an adhesive material (e.g., epoxy) that chemically bonds the head pad 200 to the head 130. In another example, the coupler 210 may be a mechanical fastener (e.g., a mechanical connector). The head pad 200 need not be formed of a metal, and may be formed of a ceramic or polymer material.

In some embodiments, the head pad 200 may be secured to the head 130 using a coupler 210, which may include any attachment structure suitable for transferring the shock wave to the head 130 while maintaining stable mechanical contact. The coupler 210 is not limited to a specific fastening mechanism and may include magnetic, adhesive, mechanical, or hybrid attachment structures.

In some embodiments, the coupler 210 may include a magnetic layer formed on either the head 130 or the head pad 200, enabling detachable attachment while maintaining uniform contact during shock wave transmission.

In some embodiments, the coupler 210 may include an adhesive layer, such as an epoxy, polymer bonding layer, silicone-based adhesive, or other bonding material capable of withstanding repeated shock wave exposure.

The coupler 210 may also include mechanical engagement structures, such as surface interlocks, protrusion–recess interfaces, or flexible retaining members that allow the pad to remain fixed during tilting motion while still permitting replacement when necessary.

A combination of adhesive, magnetic, and mechanical structures may additionally be employed to enhance durability, alignment precision, or shock wave transmission efficiency. Because the coupler 210 merely provides a structural interface between the head 130 and the head pad 200, the coupler 210 is intended to broadly encompass any structure capable of attaching the pad while allowing effective shock wave transfer.

The shock wave module 300 may be positioned over the head 130. The shock wave module 300 may be vertically spaced apart from the head pad 200 and the head 130. The shock wave module 300 may overlap the head pad 200 in the vertical direction. The shock wave module 300 may be configured to generate a shock wave and apply the shock wave to the head pad 200. The shock wave generated by the shock wave module 300 is a pressure wave, such as an acoustic wave that is transmitted through the atmosphere (of the chemical mechanical polishing apparatus) between the shock wave module 300 and head pad 200. The shock wave module 300 may be an acoustic transducer. The shock wave module 300 is an example of a pressure wave module. The shock wave module 300 may focus the shock wave onto the head pad 200 to apply pressure (e.g., a downward force) to the head pad 200 (and the head 130) in a contactless manner (i.e., the shock wave module 300 need not contact the head pad 200 or head 130 to apply pressure to the same). For example, a focal point or location of the shock wave may be on the head pad 200 or aligned with the shock wave module 300 and the head pad 200 (e.g., along a line extending between the shock wave module 300 and the head pad 200, such as in the vertical direction below the shock wave module 300).

As used herein, the term shock wave refers to a high intensity pressure wave characterized by a rapid and discontinuous rise in pressure followed by a gradual pressure decay. The shock wave may be generated by a piezoelectric acoustic transducer or an electrohydraulic acoustic transducer, and does not require the propagation speed of the wave to exceed the speed of sound in the surrounding medium. The term shock wave is intended to encompass pressure waves having the above characteristics, including acoustic pressure pulses, focused acoustic bursts, high frequency compressive waves, and transient pressure pulses capable of imparting a mechanical impulse to the head 130 or the head pad 200 through a gaseous medium. Accordingly, the shock wave as used herein is not limited to supersonic shock phenomena observed in classical fluid dynamics.

As used herein, the shock wave module 300 refers to a structural assembly configured to generate and emit a shock wave toward the head 130 or the head pad 200. The module may include one or more transducer structures such as a piezoelectric acoustic transducer, an electrohydraulic acoustic transducer, a housing or support frame, an acoustic transmission plate or film, electrical driving circuitry, and a backing member for acoustic damping or mechanical stabilization. The module may be implemented as a single integrated structure or as a multi component assembly in which the transducer, transmission plate, and support structures are separately formed and mechanically or electrically coupled. The module may further include curved, angled, or segmented surfaces that shape or direct the emitted pressure wave, along with resilient or adjustable supports that permit orientation control or vibration isolation.

In some implementations, the shock wave module 300 may include multiple transducers arranged in a linear, circular, cross shaped, or other array configuration. Such arrangements allow cooperative or synchronized emission of shock waves and represent structural variations of the module. The particular configuration of the array does not limit the scope of the module so long as the structure is capable of generating and transmitting the shock waves described herein.

In some embodiments, the shock wave generated by the shock wave module 300 transfers a mechanical force to the head 130 or the head pad 200 through impulse based pressure transfer within the surrounding gaseous medium. When the shock wave is emitted, the pressure at the leading front of the wave undergoes a rapid rise, producing a localized compressive impulse on the surface of the head pad 200. This impulse results in a momentary momentum transfer that pushes the head 130 or the head pad 200 in the direction of wave propagation. Although a low pressure region may appear behind the wave front, the shock wave module 300 may emit waves at controlled intervals so that only the forward impulse contributes meaningfully to head movement.

In some embodiments, the shock wave module 300 may emit shock waves at a predetermined repetition frequency so that the successive impulses partially overlap and produce an effective quasi continuous force on the head pad 200. This operation enables stable tilting control of the head 130 and suppresses oscillatory push pull effects.

In some embodiments, the shock wave may be directed toward a specific region of the head 130 or the head pad 200 using a curved transducer surface, an acoustic lens, or a shaped support structure. Focusing the emitted wave in this manner provides a spatially concentrated force that enhances tilting precision without requiring mechanical contact.

In some embodiments, the shock wave module 300 may include an electrohydraulic acoustic transducer configured to generate a shock wave using a spark induced pressure pulse formed within a liquid medium. The transducer may include a sealed or partially sealed chamber filled with a dielectric liquid such as deionized water, alcohol, or silicone oil, and a pair of electrodes positioned within the chamber. When a high voltage pulse is applied, a localized electrical spark is generated, which causes rapid vaporization of a portion of the liquid and forms a transient plasma bubble. The bubble expands and collapses to produce a high intensity pressure pulse that is transmitted through an acoustically permeable plate or film. The structure of the chamber, the properties of the liquid, and the acoustic impedance of the film collectively shape the emitted wave so that it exhibits the pressure profile described above.

In some embodiments, the shock wave module 300 may include a piezoelectric acoustic transducer configured to generate a shock wave by converting an electrical driving signal into a high intensity mechanical pressure pulse. The transducer may include one or more piezoelectric elements bonded to a backing structure and a front transmission plate or film formed of a material suitable for acoustic transmission. When a voltage is applied, the piezoelectric elements deform rapidly to produce a compressive displacement toward the transmission plate, where the resulting motion generates a steep fronted pressure pulse that propagates into the gaseous medium.

In some embodiments, the backing or support structure of the piezoelectric transducer may include a curved, flexible, or adjustable segment configured to change its curvature. Adjusting the curvature alters the directionality or focal characteristics of the emitted wave and enables precise control of the applied mechanical impulse. The force generated by the piezoelectric module may be controlled by regulating factors such as driving voltage amplitude, waveform, frequency, number of piezoelectric elements, curvature of the support, and the distance between the module and the head 130.

In some embodiments, the shock wave module 300 may include a transmission plate or shaped front surface that controls the spatial distribution of the emitted wave. Curved, angled, faceted, or segmented geometries may be used to steer or concentrate the acoustic energy toward a desired region of the head pad 200.

In some embodiments, multiple shock wave transducers may be arranged so that their emitted waves constructively combine at a selected focal point. By adjusting the timing, amplitude, or phase of the individual transducers, the system may direct the effective force toward different areas of the head pad 200 and achieve fine grained tilting control.

In some embodiments, the shock wave module 300 may be operated with timing and frequency control so that only the intended forward impulse contributes to the motion of the head 130. The emission timing may be synchronized with the rotational, positional, or angular state of the head so that any low pressure region behind the wave front does not interact with the same region of the head pad 200.

In some embodiments, the shock wave module 300 may emit waves at a repetition frequency that produces a cumulative force through partial overlap of successive pressure impulses. Adjusting the repetition frequency or drive amplitude allows regulation of the effective force applied to the head 130. When multiple transducers are used, their emission timing may be coordinated so that the resulting impulses reinforce one another at a desired region of the head pad 200.

A plurality of shock wave modules 300 may be provided. Each shock wave module 300 is configured to generate a shock wave independently and apply the shock wave to a corresponding head pad 200 to thereby control the tilting and angular orientation of the head 130. Tilting of the head 130 may be controlled by the shock wave generated from the shock wave module 300.

The support 400 is positioned over the head 130. The support 400 is coupled to the spindle 135. The support 400 may extend in the horizontal direction. The support 400 is spaced apart from the head pad 200 and the head 130. The support 400 may overlap the head pad 200 in the vertical direction. The support 400 may be positioned such that it is vertically aligned with each of the head pads 200.

Each shock wave module 300 is coupled to the lower surface of the support 400. Each shock wave module 300 is positioned between the support 400 and a corresponding head pad 200. Each shock wave module 300 is vertically spaced apart from the head pad 200, and does not contact a head pad 200.

The plurality of shock wave modules 300 may be provided and spaced apart from each other. A plurality of supports 400 are provided and spaced apart from each other. Each of the plurality of shock wave modules 300 may be coupled to a corresponding support 400. In some examples, plural shock wave modules 300 may be coupled to a single support 400 (and several such sets of shock wave modules 300 coupled to a corresponding support 400 may be provided in some examples).

In some embodiments, two shock wave modules 300 and two supports 400 may be provided. The support 400 may include a first support 401 and a second support 402, which may be arranged opposite to each other along a horizontal direction. For example, the first support 401 and the second support 402 may extend horizontally toward opposing sides from the spindle 135 in a plan view, wherein the opposing sides lie opposite each other relative to the spindle 135. The shock wave module 300 may include a first shock wave module 301 connected to the first support 401 and a second shock wave module 302 connected to the second support 402. The first support 401 and the second support 402 may be integrally formed (e.g., as parts of the same monolithic structure) or may be discrete separate structures.

The controller 700 may control overall operation of the chemical mechanical polishing apparatus. For example, the controller 700 may control an operation of each of the platen 110, the drive shaft 115, the head 130, the spindle 135, the slurry supply 140, the conditioner 150, the shock wave module 300, the support 400, etc. The controller 700 may control the shock wave module 300 to adjust a distance between the shock wave module 300 and the head pad 200, in which the controller is configured to increase the distance to reduce an intensity of the shock wave applied to the head pad 200, and decrease the distance to enhance the intensity of the shock wave applied to the head pad 200.

The controller 700 may be microcontroller, a logic circuit, and/or a computing device such as a workstation computer, a desktop computer, a laptop computer, or a tablet computer. For example, the controller 700 may include a memory device such as a read only memory (ROM), a random access memory (RAM), and the like, and a processor configured to perform a predetermined operation and algorithm, for example, a microprocessor, a central processing unit (CPU), a graphics processing unit (GPU), and the like. In addition, the controller 700 may include a receiver and a transmitter for receiving and transmitting an electrical signal.

In some related arts, a component for controlling the tilting of the head 130 may be in contact with the head 130. Therefore, the head 130 and the component for controlling the tilting of the head 130 may be subject to damage due to the friction force generated between the head 130 and the component for controlling the tilting of the head 130. Accordingly, periodic replacement of the head and the component may be required and accurate control of the profile of the wafer W may be limited. However, in the chemical mechanical polishing apparatus according to some embodiments, the shock wave module 300 may control the tilting of the head 130, in which the shock wave module 300 is spaced apart from and not in contact with the head 130. Accordingly, damage to the head 130 and the shock wave module 300 may be reduced, and thus replacement of components of the chemical mechanical polishing apparatus may not be necessary. In addition, the chemical mechanical polishing apparatus may control the profile of the wafer W more accurately.

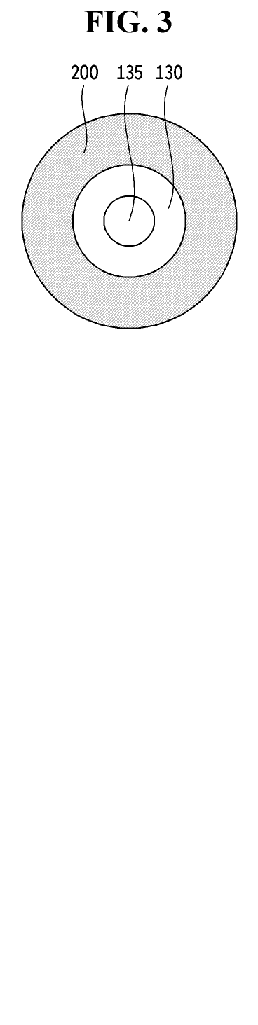

FIGS. 3 to 5 are plan views illustrating the head pad of FIG. 2.

Referring to FIG. 3, in some embodiments, the head pad 200 may have a ring shape in a plan view. The head pad 200 may be arranged to surround the spindle 135 in the plan view.

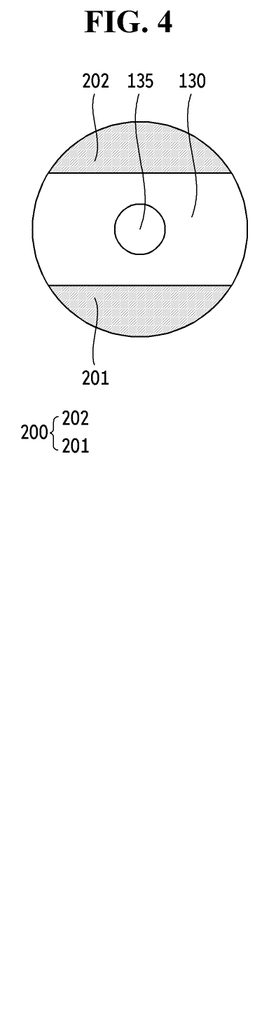

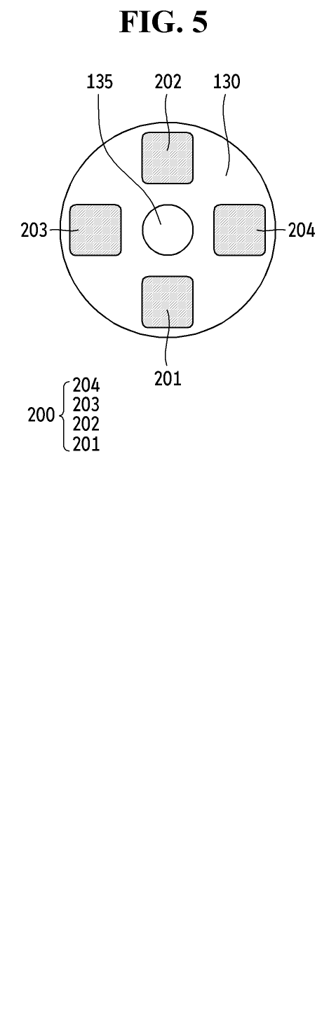

Referring to FIGS. 4 and 5, in some embodiments, a plurality of discrete head pads that are spaced apart from each other may be provided.

Referring to FIG. 4, in some embodiments, two head pads 200 may be provided. The head pad 200 may include a first head pad 201 and a second head pad 202 arranged opposite to each other in the horizontal direction. For example, the first head pad 201 and the second head pad 202 may be respectively disposed on opposing sides of the spindle 135 along a horizontal direction in a plan view, wherein the opposing sides lie opposite each other relative to the spindle 135. Each of the first head pad 201 and the second head pad 202 may have a semicircular shape in the plan view.

Referring to FIG. 5, in some embodiments, four head pads 200 may be provided. The head pad 200 may include a first head pad 201 and a second head pad 202 arranged opposite to each other along a first horizontal direction, and a third head pad 203 and a fourth head pad 204 arranged opposite to each other along a second horizontal direction. The first horizontal direction and the second horizontal direction may intersect each other. For example, the first head pad 201, the second head pad 202, the third head pad 203, and the fourth head pad 204 may be respectively disposed on opposing sides of the spindle 135 along the first and second horizontal directions in a plan view. Each of the first head pad 201, the second head pad 202, the third head pad 203, and the fourth head pad 204 may have a rectangular shape in the plan view.

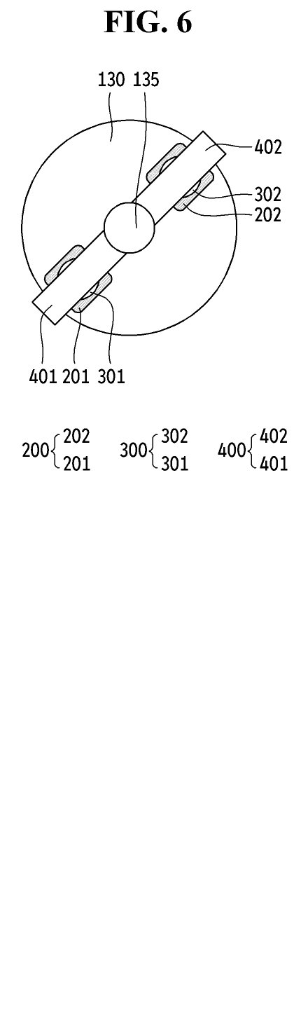

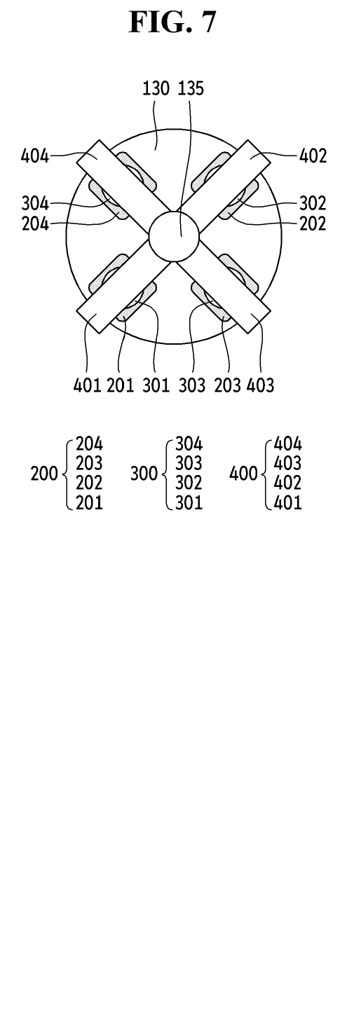

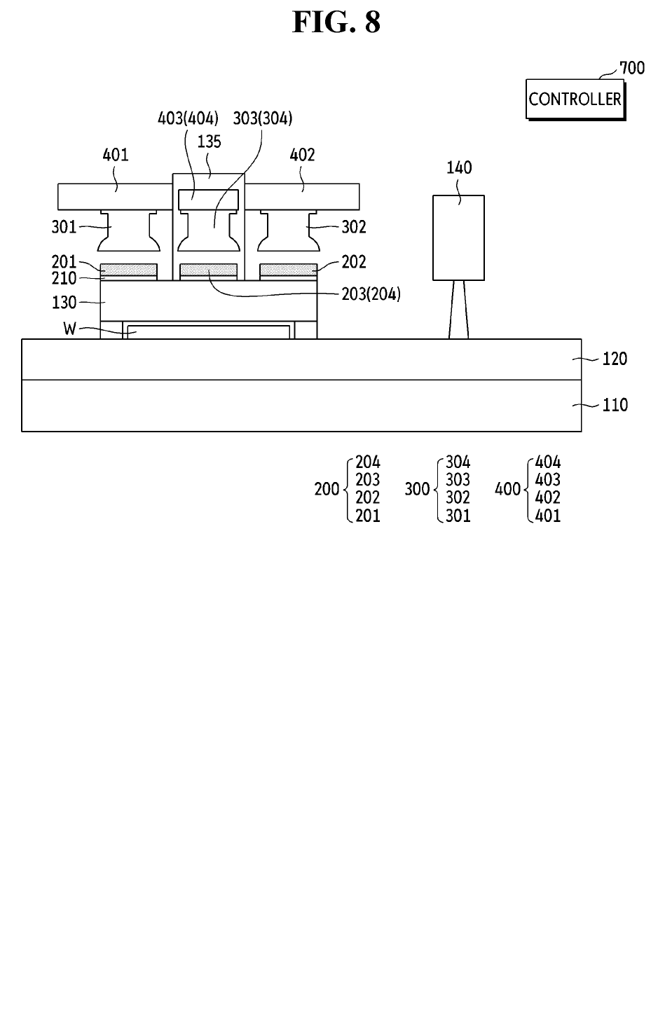

FIGS. 6 and 7 are plan views of a chemical mechanical polishing apparatus according to some embodiments. FIG. 8 is a cross-sectional view of the chemical mechanical polishing apparatus of FIG. 7. In FIGS. 6 and 7, the polishing pad 120, the slurry supply 140, the conditioner 150, and the controller 700 of FIG. 1 are not shown. In FIG. 8, the drive shaft 115 of FIG. 2 is not shown. For convenience of description, differences thereof from those described above with reference to FIGS. 1 to 5 will be mainly described.

Referring to FIG. 6, in some embodiments, two head pads 200 may be provided. The head pad 200 may include the first head pad 201 and the second head pad 202 arranged opposite to each other in a horizontal direction. For example, each of the first head pad 201 and the second head pad 202 may have a rectangular shape in a plan view. In another example, each of the first head pad 201 and the second head pad 202 may have a semicircular shape as shown in FIG. 4.

In some embodiments, each shock wave module 300 may vertically overlap a corresponding head pad 200. The first shock wave module 301 may overlap the first head pad 201 in the vertical direction, and the second shock wave module 302 may overlap the second head pad 202 in the vertical direction. Each shock wave module 300 may be positioned in vertical alignment with a corresponding head pad 200. For example, the first shock wave module 301 may be vertically aligned with the first head pad 201, and the second shock wave module 302 may be vertically aligned with the second head pad 202.

Alternatively, in some embodiments, the head pad 200 may have a circular shape as shown in FIG. 3, and each of the first shock wave module 301 and the second shock wave module 302 may overlap the head pad 200 in the vertical direction.

Referring to FIGS. 7 and 8, in some embodiments, four shock wave modules 300 and four supports 400 may be provided.

The support 400 may include component supports, including a first support 401 and a second support 402 arranged opposite to each other in the first horizontal direction, and a third support 403 and a fourth support 404 arranged opposite to each other in the second horizontal direction. The first horizontal direction and the second horizontal direction may intersect each other.

The shock wave module 300 may include a first shock wave module 301 connected to the first support 401, a second shock wave module 302 connected to the second support 402, a third shock wave module 303 connected to the third support 403, and a fourth shock wave module 304 connected to the fourth support 404.

In some embodiments, each shock wave module 300 may vertically overlap a corresponding head pad 200, such as the first head pad 201, the second head pad 202, the third head pad 203, and the fourth head pad 204. The first shock wave module 301 may overlap the first head pad 201 in the vertical direction, the second shock wave module 302 may overlap the second head pad 202 in the vertical direction, the third shock wave module 303 may overlap the third head pad 203 in the vertical direction, and the fourth shock wave module 304 may overlap the fourth head pad 204 in the vertical direction. Each shock wave module 300 may be positioned in vertical alignment with a corresponding head pad 200. For example, the first shock wave module 301 may be vertically aligned with the first head pad 201, the second shock wave module 302 may be vertically aligned with the second head pad 202, the third shock wave module 303 may be vertically aligned with the third head pad 203, and the fourth shock wave module 304 may be vertically aligned with the fourth head pad 204.

In some further embodiments, the head pad 200 may have a circular shape as shown in FIG. 3, and each of the first shock wave module 301, the second shock wave module 302, the third shock wave module 303, and the fourth shock wave module 304 may overlap the head pad 200 in the vertical direction. Each of the first to fourth shock wave modules 301 to 304 may generate a shock wave independently and apply the shock wave to corresponding portion of the head pad 200.

The numbers and arrangements of the head pads 200, the shock wave modules 300, and the supports 400 are not limited thereto, and may be variously modified.

In the chemical mechanical polishing apparatus according to some embodiments, accuracy in controlling the tilting of the head 130 may be improved by increasing the numbers of the head pads 200, the shock wave modules 300, and the supports 400 or by optimizing arrangements of the head pads 200, the shock wave modules 300, and the supports 400.

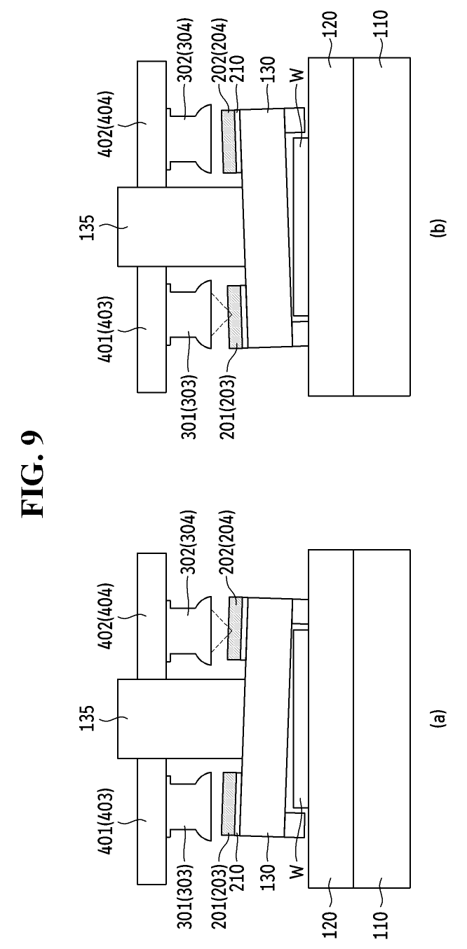

FIG. 9 is a cross-sectional view illustrating an operation of the chemical mechanical polishing apparatus of FIG. 2. In FIG. 9, the drive shaft 115, the slurry supply 140, and the controller 700 of FIG. 2 are not shown.

Referring to FIG. 9, in some embodiments, the shock wave generated from the shock wave module 300 may be transmitted to the head pad 200, which is affixed to the head 130. By applying a pressure on the head pad 200 by the shock wave, the shock wave module 300 may control the tilting of the head 130 to improve a profile of an edge area of the wafer W. For example, the tilting of the head 130 may be controlled by turning on or turning off the first to fourth shock wave modules 300 independently.

Referring to (a) in FIG. 9, when the first shock wave module 301 connected to the first support 401 is turned off and the second shock wave module 302 connected to the second support 402 is turned on, the shock wave generated from the second shock wave module 302 may be transmitted to a second portion of the head 130 positioned under the second shock wave module 302. Accordingly, the head 130 may be tilted down in a direction from the first shock wave module 301 toward the second shock wave module 302. Similarly, when the third shock wave module 303 connected to the third support 403 is turned off and the fourth shock wave module 304 connected to the fourth support 404 is turned on, the shock wave generated from the fourth shock wave module 304 may be transmitted to a fourth portion of the head 130 positioned under the fourth shock wave module 304. Accordingly, the head 130 may be tilted down in a direction from the third shock wave module 303 toward the fourth shock wave module 304.

Referring to (b) in FIG. 9, when the first shock wave module 301 connected to the first support 401 is turned on and the second shock wave module 302 connected to the second support 402 is turned off, the shock wave generated from the first shock wave module 301 may be transmitted to a first portion of the head 130 positioned under the first shock wave module 301. Accordingly, the head 130 may be tilted down in a direction (e.g., left direction) from the second shock wave module 302 toward the first shock wave module 301. Similarly, when the third shock wave module 303 connected to the third support 403 is turned on and the fourth shock wave module 304 connected to the fourth support 404 is turned off, the shock wave generated from the third shock wave module 303 may be transmitted to a second portion of the head 130 positioned under the third shock wave module 303. Accordingly, the head 130 may be tilted in a direction (e.g., left direction) from the third shock wave module 303 toward the fourth shock wave module 304.

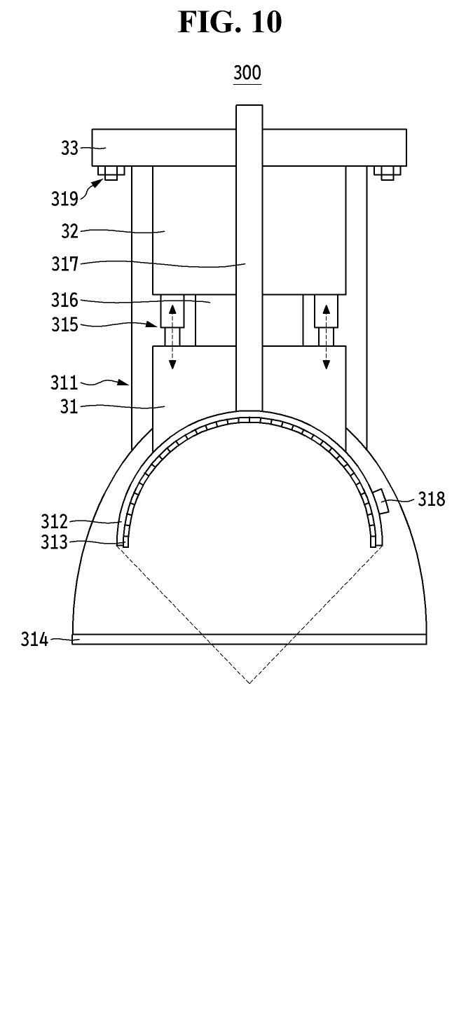

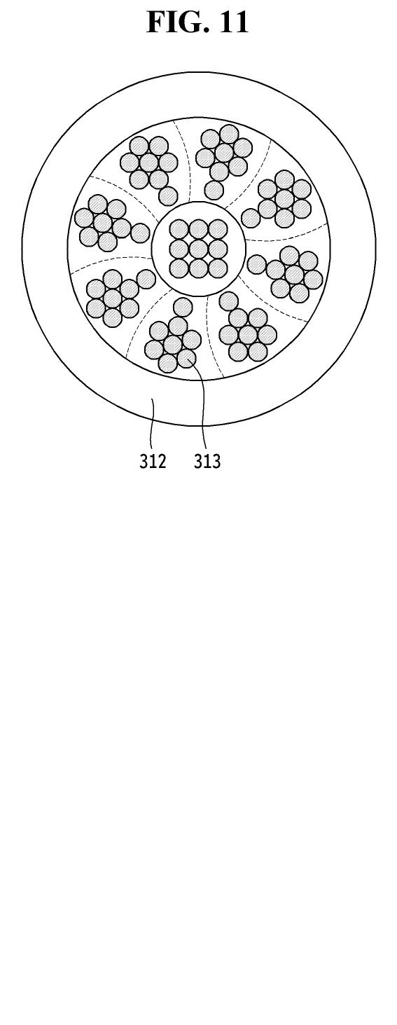

FIG. 10 is a cross-sectional view for illustrating an example of the shock wave module of FIG. 2. FIG. 11 is a plan view for illustrating a conductive support and a plurality of piezoelectric elements of FIG. 10.

Referring to FIGS. 2, 10 and 11, in some embodiments, the shock wave module 300 may comprise a piezoelectric acoustic transducer that is configured to generate shock waves in a piezoelectric manner. For example, the shock wave module 300 may include a body 311, a conductive support 312, a plurality of piezoelectric elements 313, a permeable film 314, an actuator 315, a shaft 316, an electric wire passage 317, and a pressure sensor 318.

The conductive support 312 may be disposed in the body 311. The conductive support 312 may have a dome shape and may exhibit a circular profile in a plan view. The conductive support 312 may be made of a conductive material.

The plurality of piezoelectric elements 313 may be disposed in the body 311. The plurality of piezoelectric elements 313 may be disposed on a lower surface of the conductive support 312. The plurality of piezoelectric elements 313 may be connected to the conductive support 312. The conductive support 312 may be divided into a plurality of areas, and a plurality of piezoelectric elements 313 may be disposed in each of the areas.

The piezoelectric element 313 may be configured to generate a shock wave in a piezoelectric manner. The piezoelectric element 313 may be configured to receive an electric signal via the electric wire passage 317, convert electrical energy of the electric signal into mechanical energy to generate a pressure wave (e.g., an acoustic wave), and amplify the pressure wave to generate a shock wave. The plurality of piezoelectric elements 313 may be controlled by the controller 700. The piezoelectric element 313 may generate the shock wave by the following procedures: 1) an electrical voltage is applied across the piezoelectric element 313, and it undergoes rapid mechanical deformation due to the piezoelectric effect; 2) the deformation produces a high-frequency mechanical vibration or a brief compressive pulse, depending on the waveform and energy applied to generate the pressure wave (e.g., an acoustic wave); 3) a pressure wave from each piezoelectric element 313 is transmitted to the head 130 connected to the head pad 200 where they are combined; and 4) the combined pressure waves from each piezoelectric element 313 combine to generate the shock wave.

The pressure sensor 318 may be disposed on the conductive support 312. The pressure sensor 318 may be configured to sense a pressure of the shock wave generated from the plurality of piezoelectric elements 313. The pressure of the shock wave sensed by the pressure sensor 318 may be transmitted to the controller 700.

The permeable film 314 may be disposed at one end of the body 311. The permeable film 314 may be disposed on the plurality of piezoelectric elements 313. The permeable film 314 may be made of a permeable material.

The electric wire passage 317 may be connected to the conductive support 312. An electric wire electrically connected to the conductive support 312 and the plurality of piezoelectric elements 313 may be disposed in the electric wire passage 317.

A lower support 31 and a first upper support 32 may be disposed in the body 311. The lower support 31 may be connected to the conductive support 312. The first upper support 32 may be disposed on the lower support 31. A second upper support 33 may be connected to the first upper support 32. The second upper support 33 may be disposed at the other end of the body 311. The second upper support 33 may be connected to the other end of the body 311.

The actuator 315 and the shaft 316 may be disposed between the lower support 31 and the first upper support 32. The actuator 315 and the shaft 316 may connect the lower support 31 and the first upper support 32 to each other.

The actuator 315 may be configured to extend or retract in a vertical direction. The shaft 316 and the lower support 31 may move in the vertical direction in response to extending or retracting of the actuator 315. The shaft 316 may be adjustable in length, for example, by extending or retracting its length in a telescopic manner.

In some embodiments, the shock wave module 300 may further include a fastener 319. The shock wave module 300 and the support 400 may be connected to each other via the fastener 319. The fastener 319 may be disposed on the second upper support 33. The fastener 319 may fasten the second upper support 33 to the support 400. For example, the fastener 319 may include a bolt and a nut coupled to the bolt. The bolt may be coupled to the second upper support 33 and the support 400, and the nut may be coupled to the bolt between the second upper support 33 and the support 400.

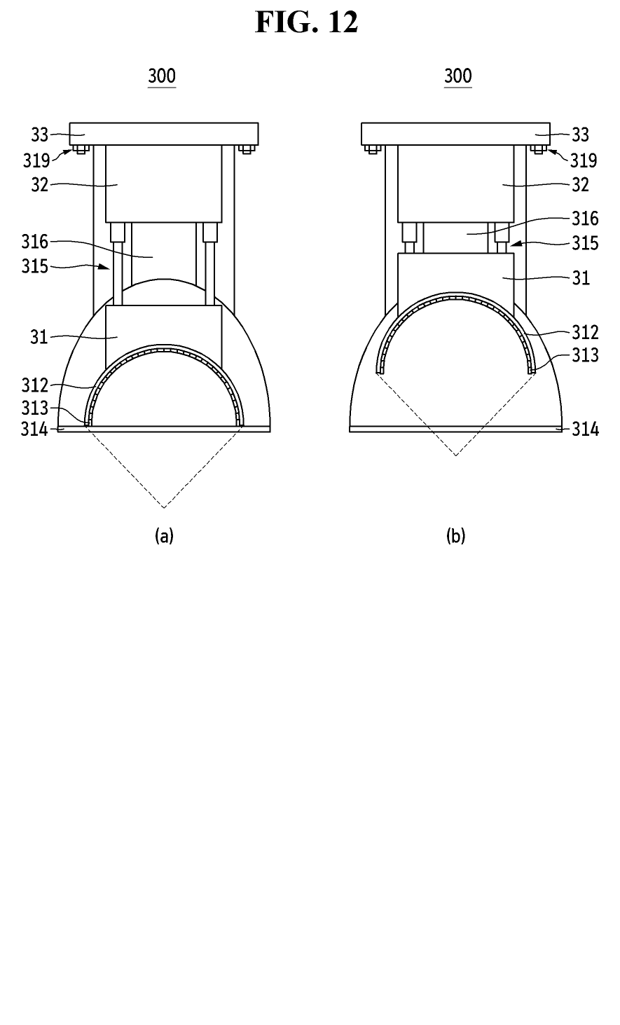

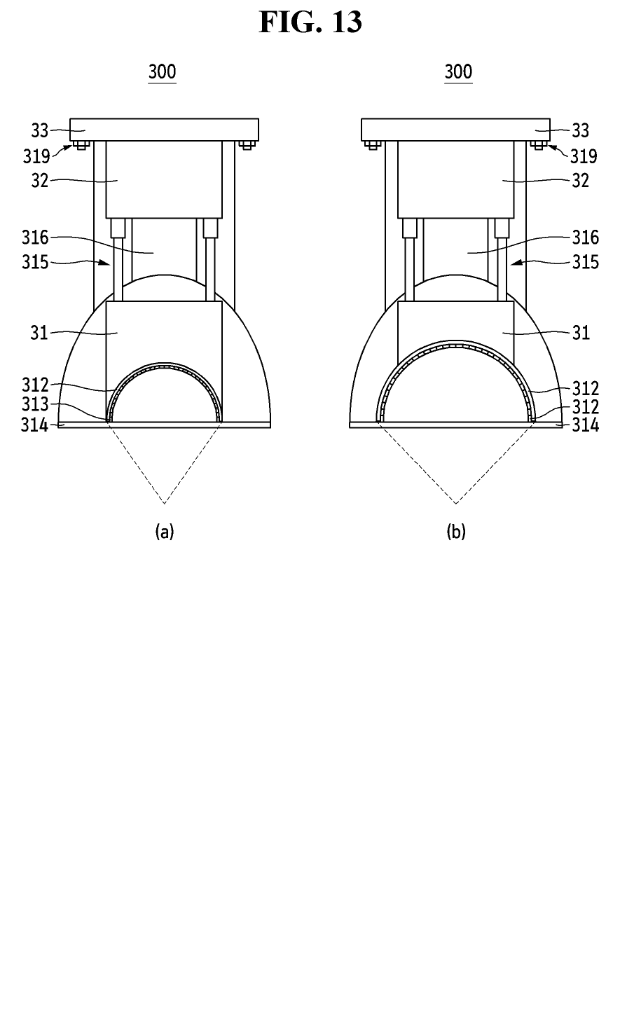

FIGS. 12 and 13 are diagrams for illustrating the operation of the shock wave module of FIGS. 10 and 11.

Referring to FIGS. 12 and 13, in some embodiments, the intensity of the shock wave generated from the shock wave module 300 and transmitted to the head 130 may be controlled based on at least one of a distance between the shock wave module 300 and the head 130 and a curvature of the conductive support 312. The conductive support 312 may reflect and focus the shock wave generated by the plurality of piezoelectric elements 313.

For example, a sensor for measuring a thickness of a corresponding wafer W may be disposed on the head 130, and the controller 700 may control the chemical mechanical polishing apparatus to increase the intensity of the shock wave provided to an area of the wafer W where the thickness of the wafer W is relatively larger, and may control the chemical mechanical polishing apparatus to decrease the intensity of the shock wave provided to an area thereof where the thickness of the wafer W is relatively smaller.

Referring to FIGS. 2 and 12, in some embodiments, the intensity of the shock wave generated from the shock wave module 300 and transmitted to the head 130 may be controlled based on the distance between the shock wave module 300 and the head 130. The distance between the shock wave module 300 and the head 130 may be adjusted by extending or retracting the actuator 315. The extending or retracting of the actuator 315 may be controlled by the controller 700.

Referring to (a) in FIG. 12, the distance between the plurality of piezoelectric elements 313 and the head 130 may be relatively reduced by extending the actuator 315. Accordingly, the intensity of the shock wave transmitted to the head 130 may be relatively increased.

Referring to (b) in FIG. 12, the distance between the plurality of piezoelectric elements 313 and the head 130 may be relatively increased by retracting the actuator 315 and the shaft 316. Accordingly, the intensity of the shock wave transmitted to the head 130 may be relatively reduced. The curvature of the conductive support 312 may focus the shock wave generated by the plurality of piezoelectric elements 313. For example, the intersection of the dashed lines in FIG. 12 may represent a focal point of the shock wave.

Referring to FIGS. 2 and 13, in some embodiments, the intensity of the shock wave generated from the shock wave module 300 may be controlled based on the curvature of the conductive support 312. The curvature of the conductive support 312 may be controlled by the controller 700. For example, an actuator for changing the curvature of the conductive support 312 may be connected to the lower support 31 under the control of the controller 700. The controller 700 may control the curvature of the conductive support, in which the controller may increase the curvature of the conductive support 312 to enhance the intensity of the shock wave, and decrease the curvature of the conductive support 312 to reduce the intensity of the shock wave. Changing the curvature of the conductive support 312 may also be used to change the focal point of the shock wave.

Referring to (a) in FIG. 13, the curvature of the conductive support 312 may be relatively increased, such that the intensity of the shock wave generated from the shock wave module 300 may be increased. Accordingly, the intensity of the shock wave transmitted to the head 130 may be relatively increased.

Referring to (b) in FIG. 13, the curvature of the conductive support 312 may be relatively reduced, such that the intensity of the shock wave generated from the shock wave module 300 may be reduced. Accordingly, the intensity of the shock wave transmitted to the head 130 may be relatively reduced.

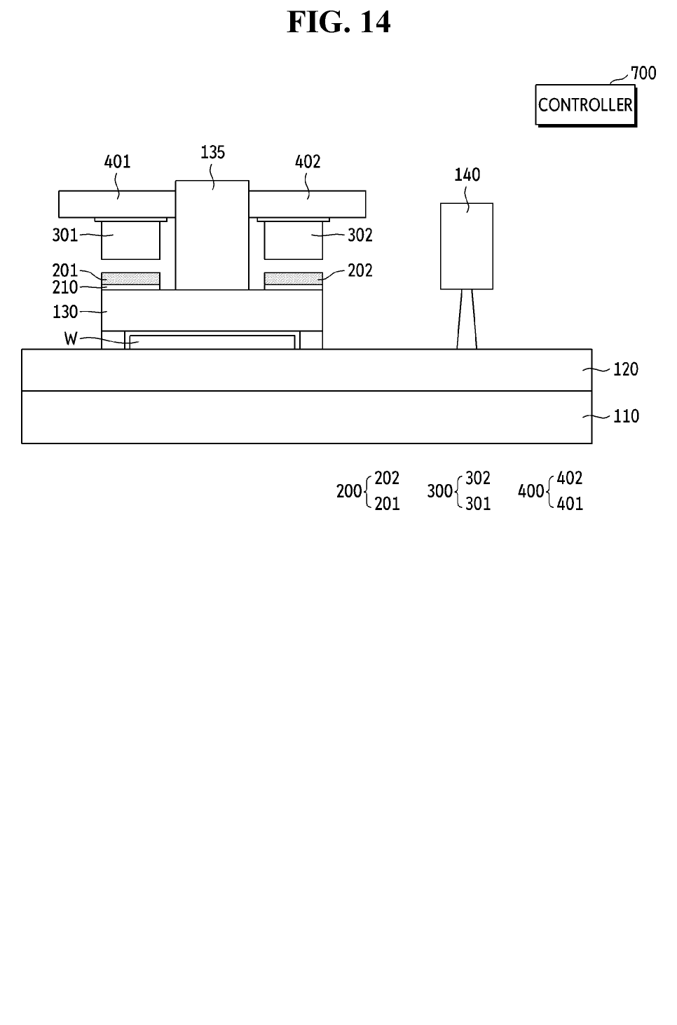

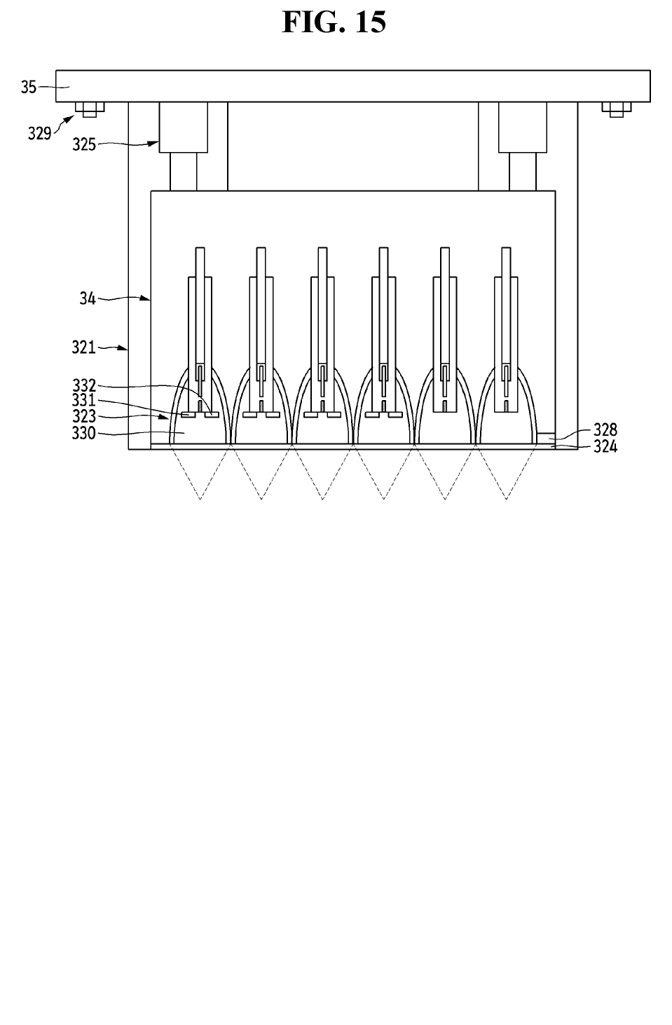

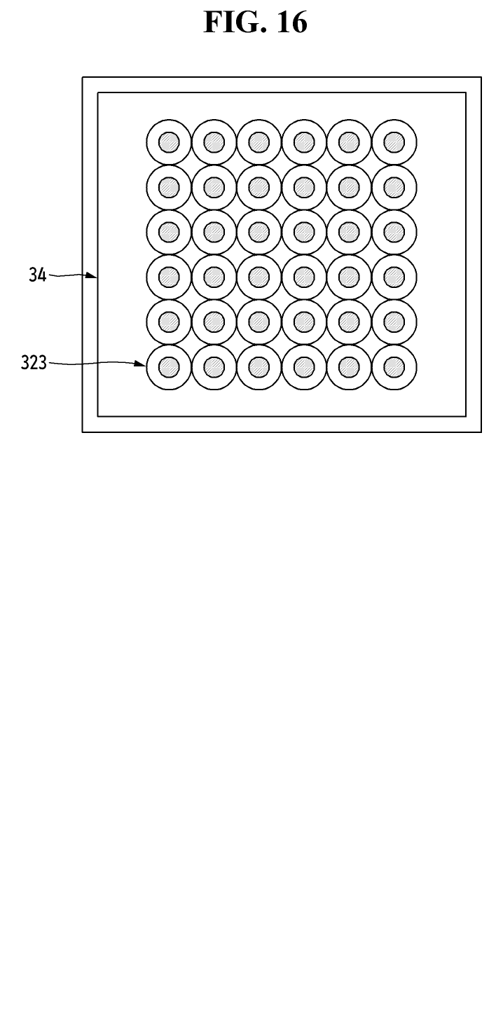

FIG. 14 is a cross-sectional view of the chemical mechanical polishing apparatus of FIG. 1. FIG. 15 is a cross-sectional view for illustrating the shock wave module of FIG. 14. FIG. 16 is a plan view for illustrating the shock wave module of FIG. 15. In FIG. 14, the conditioner 150 of FIG. 1 is not shown. For convenience of description, differences thereof from those described above with reference to FIGS. 1 to 13 will be mainly described.

Referring to FIGS. 14 through 16, in some embodiments, the shock wave module 300 may be configured to generate shock waves in an electrohydraulic manner. For example, the shock wave module 300 may include a body 321, a plurality of electrohydraulic acoustic transducers 323, a permeable film 324, an actuator 325, and a pressure sensor 328. The body 321 may have an inner space 34 defined therein. The plurality of electrohydraulic acoustic transducers 323 may be disposed in the inner space 34. The plurality of electrohydraulic acoustic transducers 323 may be arranged in a first horizontal direction and a second horizontal direction intersecting each other. A dielectric liquid 330 may be received in the inner space of the electrohydraulic acoustic transducers 323. Each electrohydraulic acoustic transducer 323 may include a pair of electrodes 331 and 332 that are spaced apart from each other within the dielectric liquid 330.

The electrohydraulic acoustic transducer 323 may be configured to generate a shock wave in an electrohydraulic manner. For example, when a high-voltage pulse is applied across the electrodes 331 and 332, a localized electrical spark may be generated in the dielectric liquid 330, causing rapid vaporization of a portion of the liquid and the formation of a transient plasma bubble. Expansion and collapse of the plasma bubble may generate a high-intensity pressure pulse that is transmitted toward the permeable film 324. The electrohydraulic acoustic transducer 323 may be configured to generate a pressure wave by forming a spark, and to generate a shock wave by amplifying the pressure wave. On/off of each electrohydraulic acoustic transducer 323 may be controlled by the controller 700.

The pressure sensor 328 may be disposed in the inner space 34. The pressure sensor 328 may be configured to sense the pressure of the shock wave generated from the plurality of electrohydraulic acoustic transducers 323. The pressure of the shock wave sensed by the pressure sensor 328 may be transmitted to the controller 700.

The permeable film 324 may be disposed at one end of the body 321. The permeable film 324 may be connected to the body 321 to define the inner space 34. The permeable film 324 may be disposed on the plurality of electrohydraulic acoustic transducers 323. The permeable film 324 may be made of a permeable material.

An upper support 35 may be disposed at the other end of the body 321. The upper support 35 may be connected to the other end of the body 321.

In some embodiments, the chemical mechanical polishing apparatus may further include a fastener 329. The shock wave module 300 and the support 400 may be connected to each other via the fastener 329. The fastener 329 may be disposed on the upper support 35. The fastener 329 may fasten the upper support 35 to the support 400. For example, the fastener 329 may include a bolt and a nut. The bolt of the upper support 35 may fasten the nut of the support 400, or the nut of the upper support 35 may fasten the bolt of the support 400.

The actuator 325 may be disposed between the upper support 35 and a portion of the body 321 defining the inner space 34. The actuator 325 may connect the upper support 35 to the portion of the body 321 defining the inner space 34.

The actuator 325 may be configured to extend or retract in a vertical direction. The portion of the body 321 defining the inner space 34 may be movable in the vertical direction via the extending or retracting of the actuator 325.

In some embodiments, two head pads 200 may be provided as shown in FIG. 4 or FIG. 6. In some embodiments, one head pad 200 may be provided as shown in FIG. 3.

In some embodiments, each of the number of the supports 400 and the number of the shock wave modules 300 may be two as shown in FIG. 1 or FIG. 6. In some embodiments, each of the number of the supports 400 and the number of the shock wave modules 300 may be four as shown in FIG. 7.

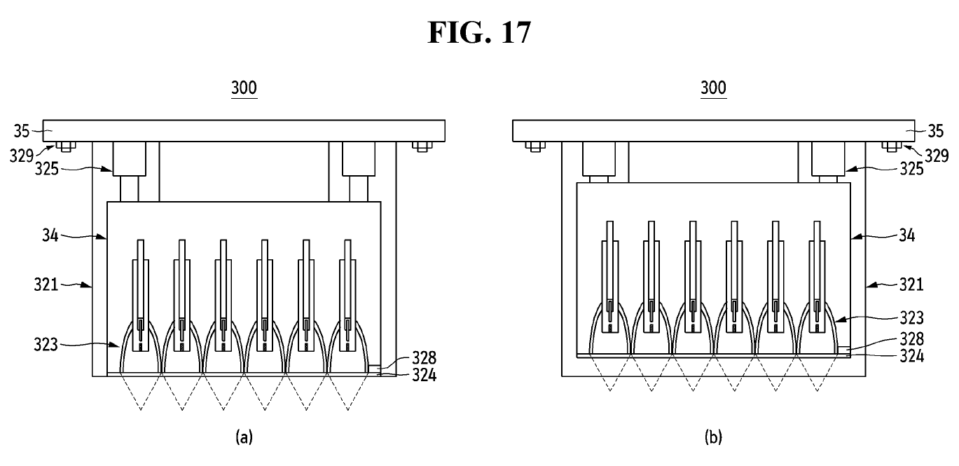

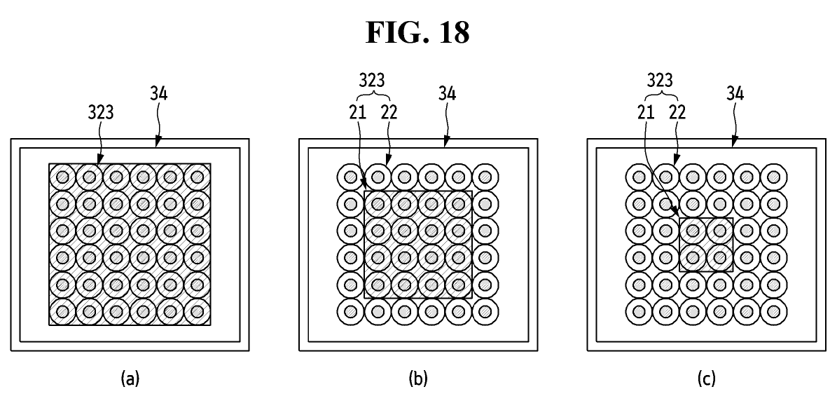

FIGS. 17 and 18 are diagrams for illustrating the operation of the shock wave module of FIGS. 15 and 16.

Referring to FIGS. 17 and 18, in some embodiments, the intensity of the shock wave generated from the shock wave module 300 and transmitted to the head 130 may be controlled based on at least one of a distance between the shock wave module 300 and the head 130 and on/off of each electrohydraulic acoustic transducer 323.

Referring to FIGS. 14 and 17, in some embodiments, the intensity of the shock wave generated from the shock wave module 300 and transmitted to the head 130 may be controlled based on the distance between the shock wave module 300 and the head 130. The distance between the shock wave module 300 and the head 130 may be adjusted via the extending or retracting of the actuator 325. The extending or retracting of the actuator 325 may be controlled by the controller 700.

Referring to (a) in FIG. 17, the distance between the plurality of electrohydraulic acoustic transducers 323 and the head 130 may be relatively reduced via the extending of the actuator 325. Accordingly, the intensity of the shock wave transmitted to the head 130 may be relatively increased.

Referring to (b) in FIG. 17, the distance between the plurality of electrohydraulic acoustic transducers 323 and the head 130 may be relatively increased via the retracting of the actuator 325. Accordingly, the intensity of the shock wave transmitted to the head 130 may be relatively reduced.

Referring to FIGS. 14 and 18, in some embodiments, the intensity of the shock wave generated from the shock wave module 300 may be controlled by turning on or off each of the plurality of electrohydraulic acoustic transducer 323.

Referring to (a) in FIG. 18, all of the plurality of electrohydraulic acoustic transducers 323 may be turned on. Accordingly, the intensity of the shock wave transmitted to the head 130 may be the maximum level.

Referring to (b) and (c) in FIG. 18, a first group of electrohydraulic acoustic transducers 21 among the plurality of electrohydraulic acoustic transducers 323 may be turned on, and the remaining electrohydraulic acoustic transducers 22 among the plurality of electrohydraulic acoustic transducers 323 may be turned off. Because greater number of electrohydraulic acoustic transducers among the plurality of electrohydraulic acoustic transducers 323 are turned on in the case of (b) compared with the case of (c), the intensity of the shock wave generated from the plurality of electrohydraulic acoustic transducers 323 in the case of (b) may be relatively greater than the intensity of the shock wave generated from the plurality of electrohydraulic acoustic transducers 323 in the case of (c).

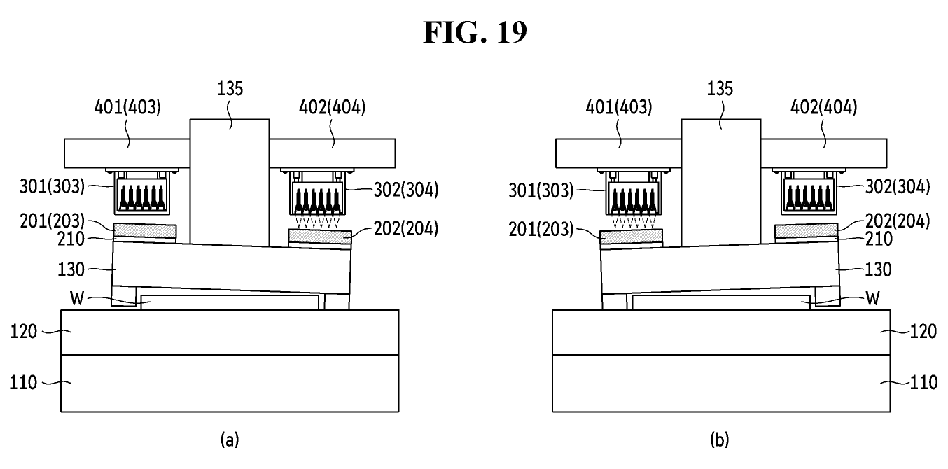

FIG. 19 is a cross-sectional view illustrating an operation of the chemical mechanical polishing apparatus of FIG. 14. In FIG. 19, the slurry supply 140 and the controller 700 of FIG. 14 are not shown.

Referring to (a) in FIG. 19, when the first shock wave module 301 connected to the first support 401 is turned off and the second shock wave module 302 connected to the second support 402 is turned on, the shock wave generated from the second shock wave module 302 may be transmitted to a portion of the head 130 positioned under the second shock wave module 302. Accordingly, the head 130 may be tilted in a direction (e.g., clockwise direction with respect to the view of FIG. 19) decreasing the distance between the head 130 and the first shock wave module 301 and increasing the distance between the head 130 and the second shock wave module 302. Similarly, when the third shock wave module 303 connected to the third support 403 is turned off and the fourth shock wave module 304 connected to the fourth support 404 is turned on, the shock wave generated from the fourth shock wave module 304 may be transmitted to a portion of the head 130 positioned under the fourth shock wave module 304. Accordingly, the head 130 may be tilted toward the third shock wave module 303 and away from the fourth shock wave module 304.

Referring to (b) in FIG. 19, when the first shock wave module 301 connected to the first support 401 is turned on and the second shock wave module 302 connected to the second support 402 is turned off, the shock wave generated from the first shock wave module 301 may be transmitted to a portion of the head 130 positioned under the first shock wave module 301. Accordingly, the head 130 may be tilted in a direction (e.g., a counterclockwise direction with respect to view of FIG. 19) decreasing the distance between the head 130 and the second shock wave module 302 and increasing the distance between the head 130 and the first shock wave module 301. Similarly, when the third shock wave module 303 connected to the third support 403 is turned on and the fourth shock wave module 304 connected to the fourth support 404 is turned off, the shock wave generated from the third shock wave module 303 may be transmitted to a portion of the head 130 positioned under the third shock wave module 303. Accordingly, the head 130 may be tilted toward the fourth shock wave module 304 and away from the third shock wave module 303.

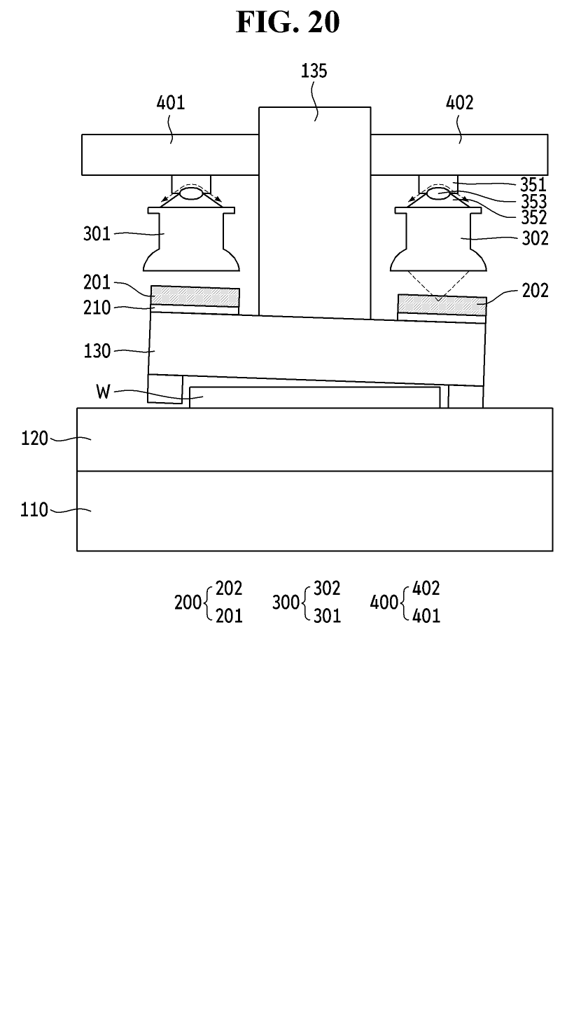

FIGS. 20 to 22 are cross-sectional views of the chemical mechanical polishing apparatus of FIG. 1. For convenience of description, differences thereof from those described above with reference to FIGS. 1 to 19 will be mainly described. In FIGS. 20 to 22, the drive shaft 115, the slurry supply 140, the conditioner 150, and the controller 700 are not shown.

Referring to FIGS. 1 and 20, in some embodiments, the shock wave module 300 and the support 400 may be connected to each other via a first connection portion 351, a second connection portion 352, and a rotatable portion 353. The first connection portion 351, the second connection portion 352, and the rotatable portion 353 may be disposed between each shock wave module 300 and each support 400.

The first connection portion 351 may be connected to the support 400. The second connection portion 352 may be connected to the shock wave module 300. The rotation portion 353 may connect the first connection portion 351 and the second connection portion 352 to each other.

The rotatable portion 353 may be configured to permit rotational movement relative to the first connection portion 351. The rotatable portion 353 may be configured to be rotatable in a clockwise direction or a counterclockwise direction on a plane parallel to an upper surface of the head 130 and to move in a vertical direction to which the spindle 135 extends. For example, the rotatable portion 353 may be configured to be rotatable in a clockwise direction or a counterclockwise direction on a plane across which the support 400 extends and to be movable in the vertical direction to which the spindle 135 extends. The second connection portion 352 and the shock wave module 300 may be pivotable as the rotatable portion 353 rotates. The rotatable portion 353 may be controlled by the controller 700. The pivoting of each shock wave module 300 may be controlled based on the rotation of the rotatable portion 353, and a specific portion of the head 130 to which the shock wave is transmitted may be finely adjusted. Therefore, the profile of the edge area of the wafer W may be more finely controlled.

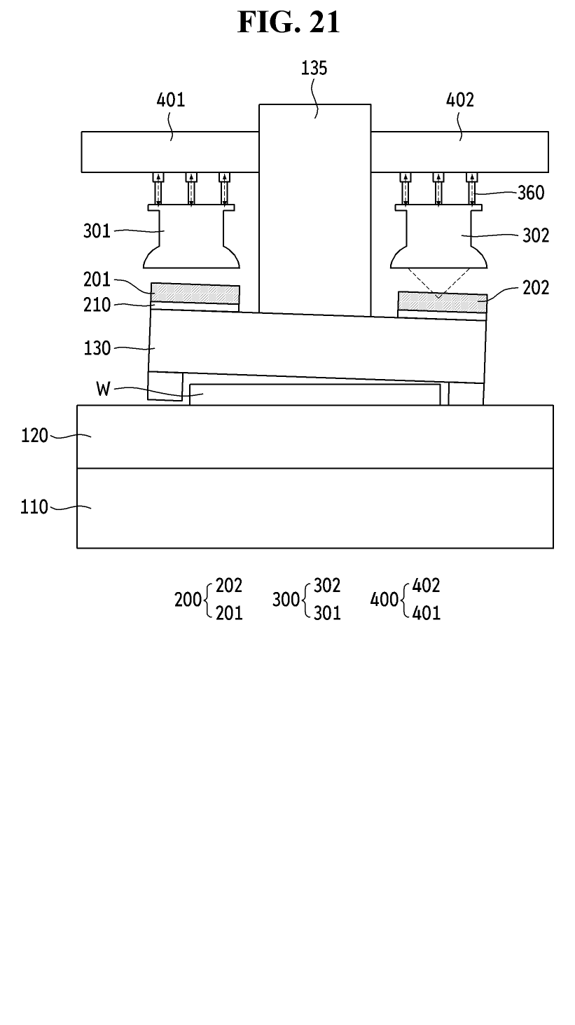

Referring to FIGS. 1 and 21, in some embodiments, the shock wave module 300 and the support 400 may be connected to each other via a plurality of length-adjustable rods 360. The plurality of length-adjustable rods 360 may be spaced apart from each other. The plurality of length-adjustable rods 360 may be disposed between each shock wave module 300 and each support 400.

Each length-adjustable rod 360 may be configured to be extendable in a vertical direction. A length of each length-adjustable rod 360 may be controlled by the controller 700. The length-adjustable rods 360 may be independently extendable in the vertical direction. Therefore, the extensions of the respective length-adjustable rods 360 may be controlled such that the vertical lengths of the respective length-adjustable rods 360 may be different from each other. Thus, the tilting of each shock wave module 300 may be controlled, and a specific portion of the head 130 to which the shock wave generated from the shock wave module 300 is transmitted may be finely adjusted. Accordingly, the profile of the edge area of the wafer W may be more finely controlled.

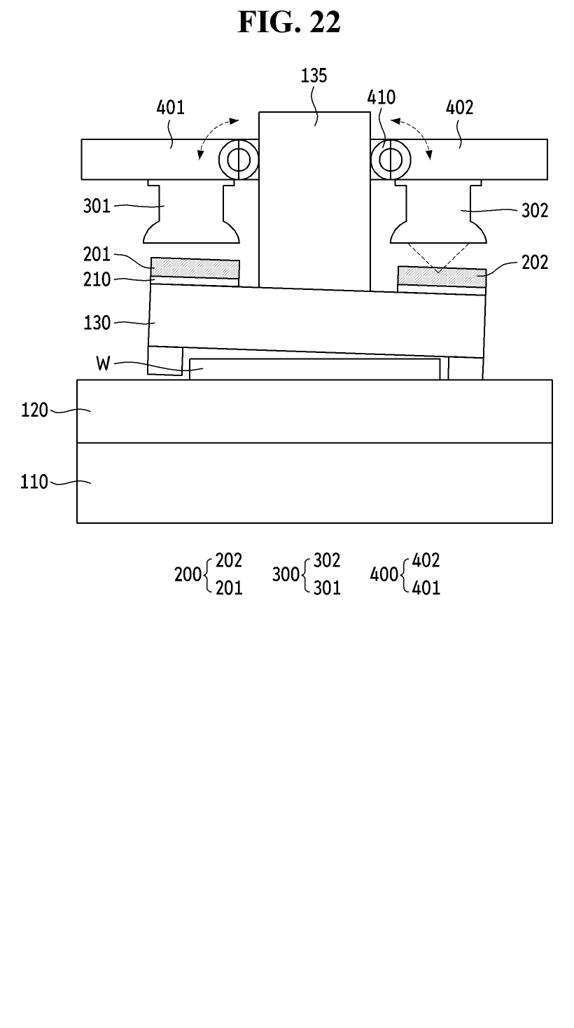

Referring to FIGS. 1 and 22, in some embodiments, the support 400 may be connected to the spindle 135 via a joint 410. The joint 410 may be configured to be rotatable relative to the spindle 135. The joint 410 may be configured to be rotatable clockwise or counterclockwise on a plane across which the support 400 extends and a vertical direction to which the spindle 135 extends. The support 400 and the shock wave module 300 may be pivotable via the rotation of the joint 410. The rotation of the joint 410 may be controlled by the controller 700. The tilting of each shock wave module 300 may be controlled based on the rotation of the joint 410, and the shock wave generated from the shock wave module 300 may be transmitted to a specific area of the wafer W. The profile of the edge area of the wafer W may be more finely controlled.

Referring to FIGS. 20 to 22, in some embodiments, each of the number of the head pads 200, the number of the shock wave modules 300, and the number of the supports 400 may be two. The number of the head pads 200 may be two as shown in FIG. 4 or FIG. 6. Alternatively, in some embodiments, the head pad 200 may have a circular or disc shape as shown in FIG. 3 that is concentric with the spindle 135 (e.g., the spindle 135 is located at the center of the circular boundaries of the disc shape).

Alternatively, in some embodiments, each of the number of the head pads 200, the number of the shock wave modules 300, and the number of the supports 400 may be four as shown in FIG. 7.

In some embodiments, the shock wave module 300 may be configured to generate shock waves in a piezoelectric manner as in FIGS. 10 and 11. Alternatively, in some embodiments, the shock wave module 300 may be configured to generate shock waves in an electrohydraulic manner, such as illustrated in FIGS. 15 and 16.

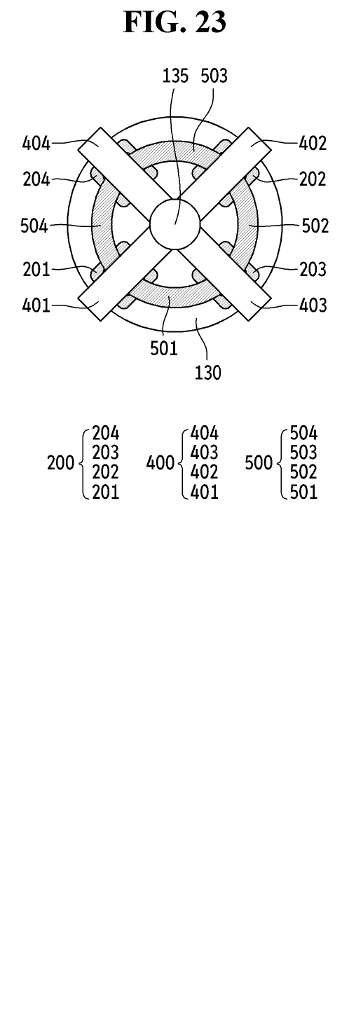

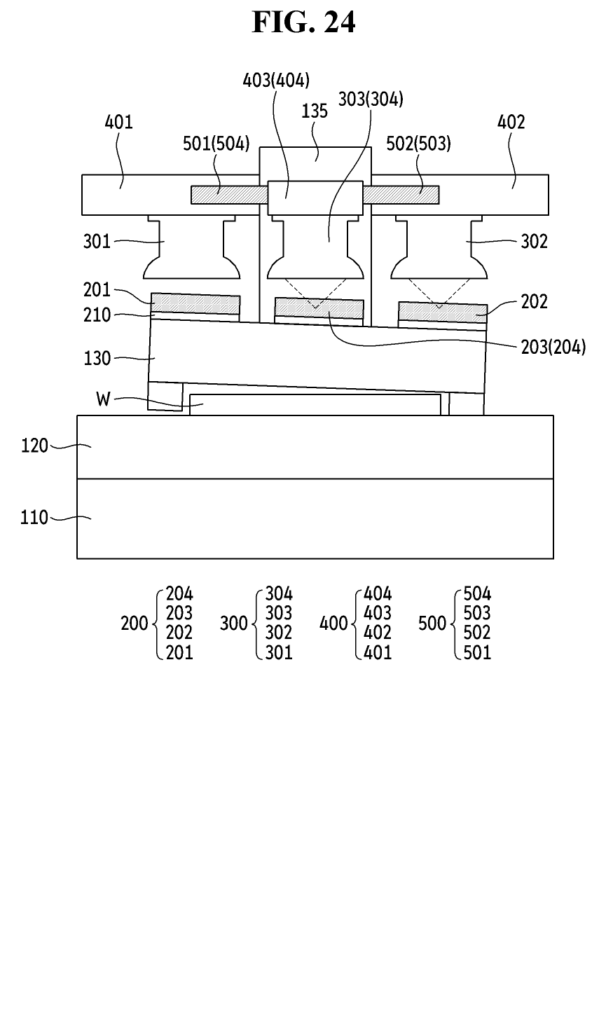

FIG. 23 is a plan view of a chemical mechanical polishing apparatus according to some embodiments. FIG. 24 is a cross-sectional view of the chemical mechanical polishing apparatus of FIG. 23. For convenience of description, differences thereof from those described above with reference to FIGS. 1 to 22 will be mainly described.

Referring to FIGS. 23 and 24, the chemical mechanical polishing apparatus according to some embodiments may further include an auxiliary support 500. The auxiliary support 500 may be connected between adjacent supports 400. The auxiliary support 500 may be disposed between side surfaces of adjacent supports 400. Accordingly, the stability of the support 400 may be improved and/or enhanced.

For example, the auxiliary support 500 may include a first auxiliary support 501 connecting the first support 401 and the third support 403 to each other, a second auxiliary support 502 connecting the third support 403 and the second support 402 to each other, a third auxiliary support 503 connecting the second support 402 and the fourth support 404 to each other, and a fourth auxiliary support 504 connecting the fourth support 404 and the first support 401 to each other.

In some embodiments, each of the number of the head pads 200, the number of the shock wave modules 300, and the number of the supports 400 may be four. Alternatively, in some embodiments, the head pad 200 may have a circular shape as shown in FIG. 3.

In addition, in some embodiments, each of the number of the head pads 200, the number of the shock wave modules 300, and the number of the supports 400 may be two as shown in FIG. 6, and the number of the auxiliary supports 500 may be two.

In some embodiments, the shock wave module 300 may be configured to generate shock waves in a piezo-electric manner as in FIGS. 10 and 11. Alternatively, in some embodiments, the shock wave module 300 may be configured to generate shock waves in an electrohydraulic manner, such as illustrated in FIGS. 15 and 16.

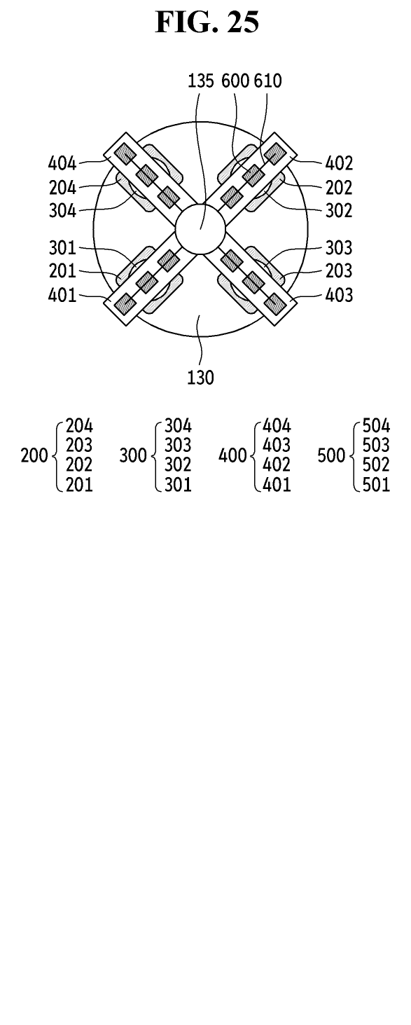

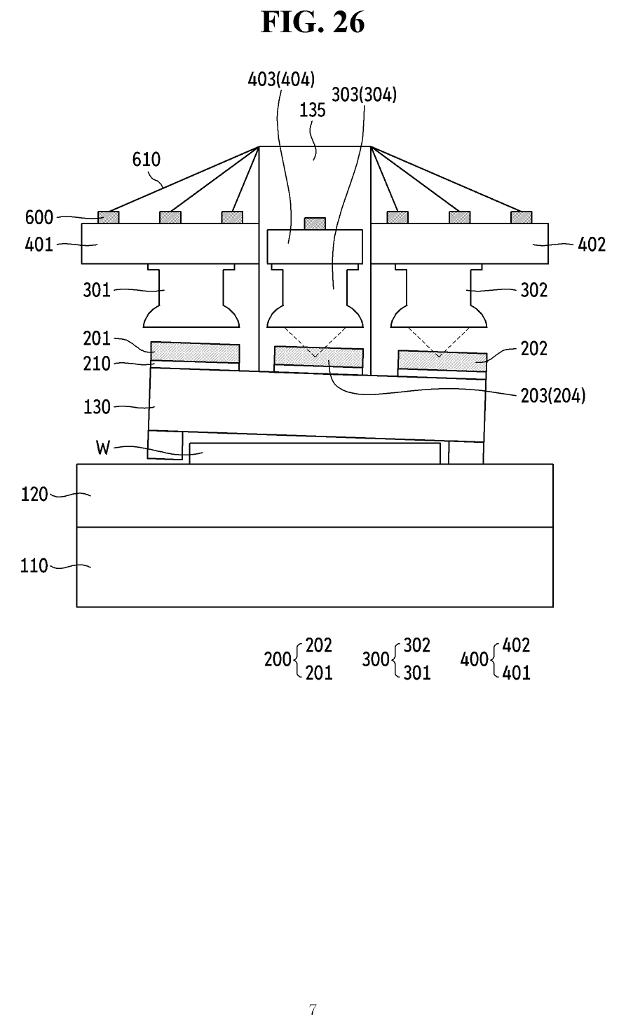

FIG. 25 is a plan view for illustrating the auxiliary support of the chemical mechanical polishing apparatus according to some embodiments. FIG. 26 is a cross-sectional view of the chemical mechanical polishing apparatus of FIG. 25.

Referring to FIGS. 25 and 26, the chemical mechanical polishing apparatus according to some embodiments may further include a fixing point 600 and a cable 610.

The fixing point 600 may be disposed on each support 400. A plurality of fixing points 600 may be disposed on each support 400 and spaced from each other. The cable 610 may connect the fixing points 600 to the spindle 135. Accordingly, the stability of the support 400 may be improved and/or enhanced.

In some embodiments, each of the number of the head pads 200, the number of the shock wave modules 300, and the number of the supports 400 may be four. Alternatively, in some further embodiments, the head pad 200 may have a circular shape as shown in FIG. 3.

In addition, in some further embodiments, each of the number of the head pads 200, the number of the shock wave modules 300, and the number of the supports 400 may be two as shown in FIG. 6, and the number of the auxiliary supports 500 may be two.

In some embodiments, the shock wave module 300 may be configured to generate shock waves in a piezo-electric manner as in FIGS. 10 and 11. Alternatively, in some further embodiments, the shock wave module 300 may be configured to generate shock waves in an electrohydraulic manner, such as in FIGS. 15 and 16. It will be appreciated that other types of acoustic transducers may be implemented other than the piezoelectric acoustic transducers and electrohydraulic acoustic transducers disclosed herein.

Although embodiments of the present disclosure have been described above with reference to the accompanying drawings, the present invention is not to be limited to embodiments and may be implemented in various different forms. Therefore, it should be understood that embodiments as described above are not restrictive but illustrative in all respects.

What is claimed is:

1. A chemical mechanical polishing apparatus comprising:
a head configured to mount a wafer thereon;
a spindle vertically extending from the head;
a support horizontally extending from the spindle; and
a shock wave module disposed on a lower surface of the support, and configured to generate a shock wave that is applied to the head.

2. The chemical mechanical polishing apparatus of claim 1, wherein the shock wave module includes:
a body having an inner space defined therein; and
electrohydraulic acoustic transducers received in the inner space.

3. The chemical mechanical polishing apparatus of claim 2, wherein the shock wave module further includes an actuator configured to move the electrohydraulic acoustic transducers in a vertical direction.

4. The chemical mechanical polishing apparatus of claim 2, further comprising:
a controller configured to control a number of electrohydraulic acoustic transducers that are turned-on in the shock wave module to generate the shock wave,
wherein the controller is configured to increase the number to enhance an intensity of the shock wave and to decrease the number to reduce the intensity of the shock wave.

5. The chemical mechanical polishing apparatus of claim 1, wherein the shock wave module includes:
a body;
a conductive support in the body; and
a plurality of piezoelectric elements disposed on a lower surface of the conductive support that are configured to generate the shock wave.

6. The chemical mechanical polishing apparatus of claim 5, wherein the shock wave module further includes a lower support in contact with an upper surface of the conductive support to change a curvature of the conductive support.

7. The chemical mechanical polishing apparatus of claim 6, wherein the shock wave module further includes an actuator connected to the lower support, and the actuator is configured to move the lower support in a vertical direction to change the curvature of the conductive support.

8. The chemical mechanical polishing apparatus of claim 7, further comprising:
a controller configured to control the actuator to change the curvature of the conductive support,
wherein the controller is configured to control the actuator to increase the curvature of the conductive support to enhance an intensity of the shock wave and to control the actuator to decrease the curvature of the conductive support to reduce the intensity of the shock wave.

9. The chemical mechanical polishing apparatus of claim 1, further comprising:
a length-adjustable rod configured to connect the support and the shock wave module to each other,
wherein the length-adjustable rod is configured to extend or retract in a vertical direction to adjust a vertical length of the length-adjustable rod, thereby adjusting a distance between the shock wave module and the head.

10. The chemical mechanical polishing apparatus of claim 1, further comprising:
a first connection portion connected to the support;
a second connection portion connected to the shock wave module; and
a rotatable portion configured to connect the first connection portion and the second connection portion to each other and to rotate relative to the first connection portion.

11. The chemical mechanical polishing apparatus of claim 1, further comprising a controller configured to adjust the shock wave module to adjust a location of a focal point of the shock wave generated by the shock wave module.

12. The chemical mechanical polishing apparatus of claim 1, a controller configured to adjust a distance between the shock wave module and the head to adjust an intensity of the shock wave applied to the head.

13. A chemical mechanical polishing apparatus comprising:
a head configured to mount a wafer thereon;
a spindle connected to the head;
a support connected to the spindle;
a head pad disposed on an upper surface of the head;
a coupler disposed between the head and the head pad; and
a shock wave module connected to a lower surface of the support, and configured to generate a shock wave and apply the shock wave to the head pad,
wherein the shock wave module is spaced apart from the head pad.

14. The chemical mechanical polishing apparatus of claim 13,
wherein the head pad is formed of a metal, and
wherein the coupler is formed of a magnetic material to provide a magnetic attachment to the head pad.

15. The chemical mechanical polishing apparatus of claim 13,
wherein the head pad is formed of a ceramic or polymer, and
wherein the coupler is an epoxy.

16. The chemical mechanical polishing apparatus of claim 13, wherein the head pad has a disc shape that is concentric with the spindle.

17. The chemical mechanical polishing apparatus of claim 13, comprising a plurality of shock wave modules and a plurality of head pads, each of the plurality of shock wave modules being spaced apart from a corresponding one of the plurality of head pads.

18. The chemical mechanical polishing apparatus of claim 17, wherein each of the plurality of shock wave modules is vertically aligned with the corresponding one of the plurality of head pads.

19. A chemical mechanical polishing apparatus comprising:
a head configured to mount a wafer thereon;
a spindle vertically extending from the head;
a plurality of supports each extending from the spindle horizontally;
a plurality of head pads disposed on the head; and
a plurality of shock wave modules, each connected to a lower surface of a corresponding support and positioned vertically above a corresponding head pad to generate and apply a shock wave to the corresponding head pad.

20. The chemical mechanical polishing apparatus of claim 19, further comprising a controller configured to individually control timing and intensity of the shock waves generated by the plurality of shock wave modules.
